(19) United States
(12) Patent Application Publication
(10) Pub. No.: US 2026/0360407 A1
(43) Pub. Date: Nov. 12, 2026

(54) HIERARCHICAL SELECT GATE DRAIN STRUCTURES

(71) Applicant: Micron Technology, Inc., Bosie, ID (US)

(72) Inventors: Tomoharu Tanaka, Yokohama (JP); Yoshiaki Fukuzumi, Yokohama (JP)

(73) Assignee: Micron Technology, Inc., Boise, ID (US)

(21) Appl. No.: 19/653,705

(22) Filed: Apr. 21, 2026

Related U.S. Application Data
(60) Provisional application No. 63/804,523, filed on May 12, 2025.

(51) Int. Cl. G11C 11/408; G11C 5/06; G11C 11/4091; G11C 11/4094; G11C 16/04; G11C 16/08; G11C 16/24; G11C 16/26; H10B 41/27; H10B 41/40; H10B 43/27; H10B 43/40; H10W 20/41

(52) U.S. Cl. CPC G11C 11/4082; G11C 5/063; G11C 11/4091; G11C 11/4094; G11C 16/0483; G11C 16/08; G11C 16/24; G11C 16/26; H10B 41/27; H10B 41/40; H10B 43/27; H10B 43/40; H10W 20/435

(57) ABSTRACT

A three-dimensional memory device comprising an array of memory cells comprising a plurality of sets of memory strings is provided. The three-dimensional memory device further comprises a global bit line, a first tier select gates, a dynamic latch device connected between the global bit line and the first tier select gates, and a second tier select gates connected between the first tier select gates and the plurality of sets of memory strings. The three-dimensional memory device further comprises a controller configured to control the first tier select gates and the second tier select gates to cause multiple selected memory strings of the plurality of sets of memory strings to be read using the dynamic latch device.

### CROSS REFERENCE TO RELATED APPLICATIONS

This application claims priority to U.S. Application No. 63/804,523, filed on May 12, 2025, and is entitled “HIERARCHICAL SELECT GATE DRAIN STRUCTURES,” the content of which is incorporated by reference herein in its entirety for all purposes.

### TECHNICAL FIELD

This disclosure relates to one or more systems for memory, including techniques of hierarchical select gate drain (SGD) structures for performing a group read operation of a memory array in a three-dimensional memory device.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 3 is a block diagram of an example apparatus for implementing one or more systems and for performing one or more methods described herein, in accordance with examples as disclosed herein.

FIG. 4 is a diagram illustrating a configuration of a three-dimensional memory device having a dynamic latch device and non-hierarchical select gate drain (SGD) transistors.

FIGS. 5A and 5B are diagrams illustrating an example of a three-dimensional memory device having a dynamic latch device and hierarchical select gate drain (SGD) structures according to some embodiments.

FIG. 6 is a diagram illustrating waveforms of signals associated with data access operations using a dynamic latch device and the hierarchical SGD structures based on a single read pulse according to some embodiments.

FIG. 7 is a flowchart illustrating an example method for performing a data access operation of a memory array of a three-dimensional memory device using hierarchical SGD structures according to some embodiments.

### DETAILED DESCRIPTION

A three-dimensional memory device typically includes an array of memory cells. The array includes many memory strings. A memory string includes many memory cells and a memory string is sometimes also referred to as a sub-block. A memory string can be coupled to one or more select gate drains (SGDs). An SGD can include, for example, one or more transistors. An SGD can be controlled to select a corresponding one of the one or more memory strings during a data access operation (e.g., a read operation). In this disclosure, SGD may also be referred to select gates or select transistors. In some examples, the memory device can also include one or more dynamic latch devices coupled to the memory strings. During the data access operations, a dynamic latch device can be used to increase the read operation efficiency and performance. For example, a dynamic latch device can facilitate read operations from multiple memory strings to be performed using a single read pulse. In one memory device structure, the SGDs can be connected between the dynamic latch device and multiple memory strings. The dynamic latch device and the memory strings may also be coupled to data storage nodes configured to store data (e.g., using capacitors) during the data access operations.

In an example configuration, each memory string is coupled to an independent SGD for controlling the selection or deselection of the memory string. For example, if there are four memory strings, there can be four SGDs arranged in a horizonal direction in the chip layout. However, it becomes more and more challenging to form independent SGDs side-by-side in the horizontal direction as the memory cells’ horizontal dimensions are being scaled down. When the dimensions are scaled down, the space between the adjacent independent SGDs becomes narrower and narrower. In some situations, the layout area may not be sufficient to accommodate all the independent SGDs along the horizontal direction.

To solve the limited layout area space issue, logical SGDs with a combination of voltages are used as selectors in the data access (e.g., read) operations. Compared to independent SGDs, logical SGDs include logic gates (e.g., OR gate, NOR gate, AND gate, NAND gate, etc.) to implement the same or similar functions of a plurality of independent SGDs. For example, logical SGDs may use two input signals (and two inverse of the input signals) and a combination of logical gates to implement the same function of controlling four select gates independently (e.g., when the two input signals are 00, 01, 10, and 11, the logical SGDs can be controlled to generate 4 different output signals, each controlling the selection of one particular memory string as if the particular memory string is controlled by an independent SGD.

There may be certain problems associated with using logical SGDs. For example, by using the logical SGDs, charges on the capacitors of the data storage nodes are shared with a sensing node of the dynamic latch device. Thus, the sensing node of the dynamic latch device may have a relatively large parasitic capacitance, because of the logical SGD structure (e.g., more transistors are needed to implement the logical SGD structure compared to independent SGDs). Due to the large parasitic capacitance, noise is increased and in turn, the signal-to-noise ratio becomes worse when performing data access operations (e.g., read or program verify operations). Therefore, there is a need for techniques to reduce parasitic capacitance and increase signal-to-noise ratio while logical SGDs are used to perform, for example, a group read operation of a memory array of a three-dimensional memory device.

The present disclosure provides techniques of using hierarchical SGD structures to reduce parasitic capacitance and increase signal-to-noise ratio for performing data access (e.g., a group read) operations of a memory array of a three-dimensional memory device. Unlike the logical SGD structure, the hierarchical SGD structure includes multiple tiers of select gates, for example, a first tier and a second tier. The first tier select gates and the second tier select gates can be controlled by control logic of the memory device. The control logic can be a system controller external to the memory device or a local controller internal to the memory device. The control logic can be configured to control the first tier select gates and the second tier select gates to cause multiple selected memory strings to be read using the dynamic latch device based on a single read pulse. As described in more detail below, the hierarchical SGD structure solves the above-identified problems by separating the SGDs to two or more tiers. Combined with the dynamic latch device, the hierarchical SGD structure can reduce the parasitic capacitance at the sensing node and therefore improve the signal-to-noise ratio, while still providing the benefit of implementing the control functions using limited layout space area. More details of the techniques are described below.

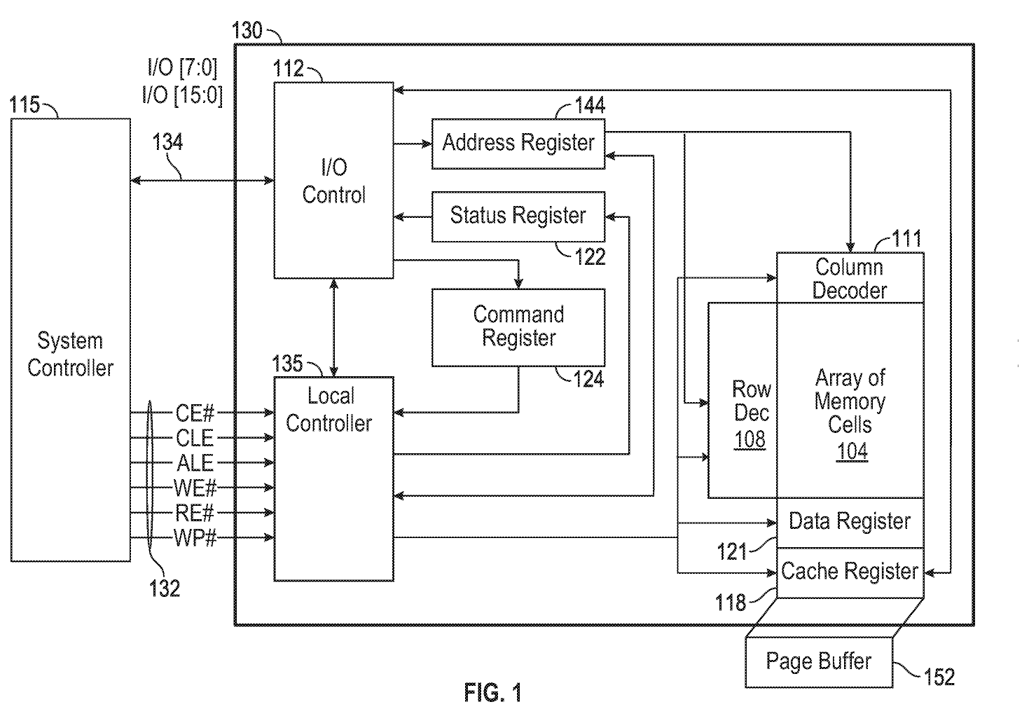

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some examples, local controller 135 communicates with the external system controller 115, which may be a host controller (e.g., an UFS or eMMC controller, or a CPU communicating with local controller 135) located in a host system or a memory system controller located in a memory system. Local controller 135 can be disposed on the same semiconductor die as the memory array (e.g., array 104), and a separate system controller 115 can be disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. One or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some examples, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

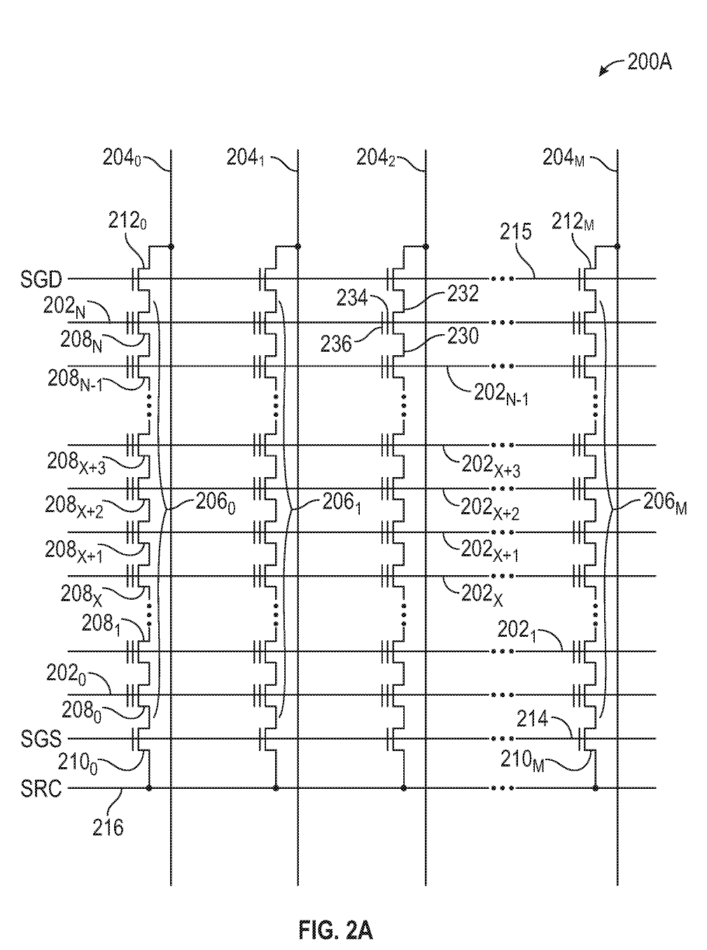

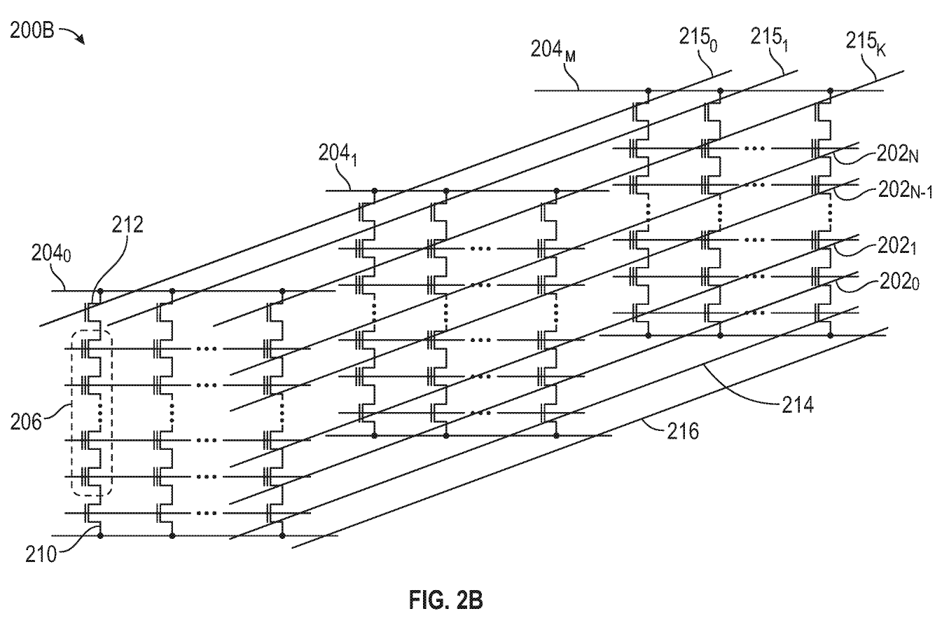

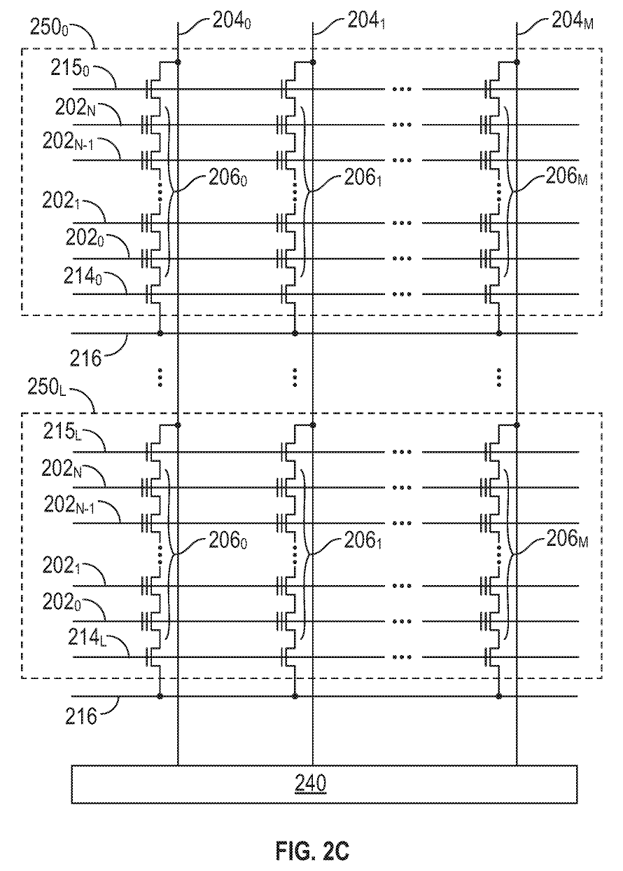

FIGS. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In other embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. The blocks 250 are shown in FIG. 2C using dashed lines to illustrate that certain numbers of memory cells can be group together for certain operations. For instance, blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀can be a same source as the source 216 for the block of memory cells 250_{L}. For example, each block of memory cells 250₀-250_{L}can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

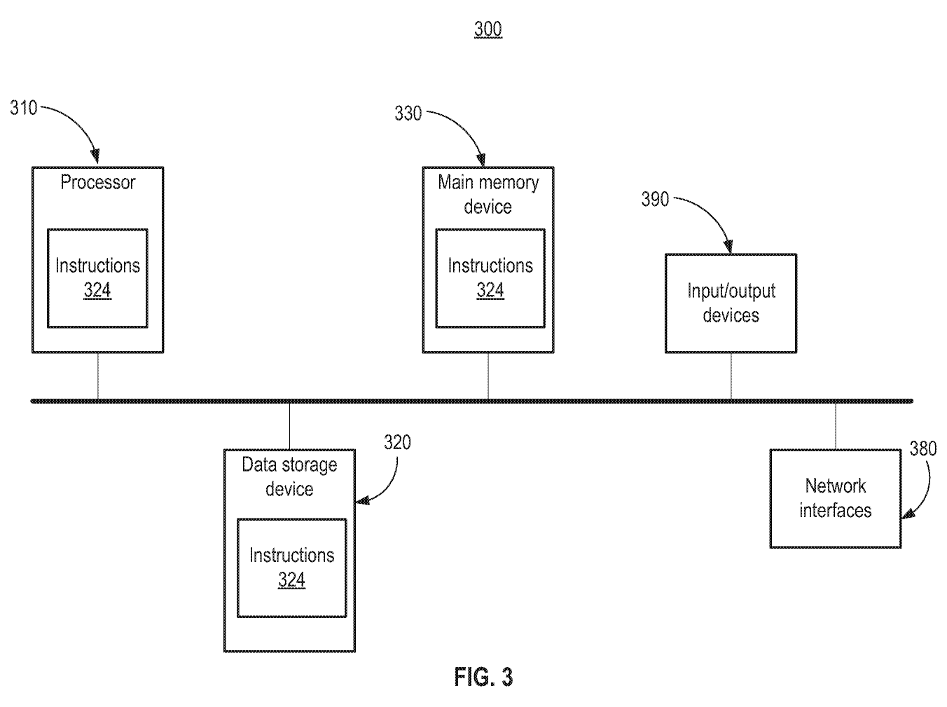

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and blocks described herein, including one or more of the blocks of at least some of the FIGS. 1-7, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

Apparatus 300 includes a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 if the computer program instructions is desired. For example, processor 310 may be used to implement one or more components and systems described herein, such as system controller 115 and/or local controller 135 (shown in FIG. 1). Thus, the method blocks of processes in at least some of FIGS. 1-7 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method processes or blocks discussed herein in connection with at least some of FIGS. 1-7. Accordingly, by executing the computer program instructions, processor 310 executes an algorithm defined by the method processes or blocks of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may include one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each include a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

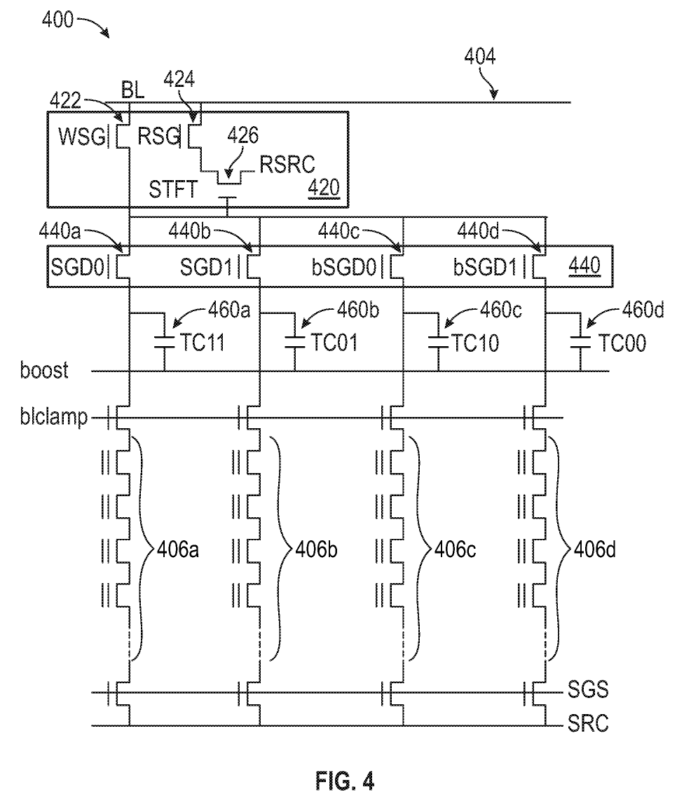

FIG. 4 is a diagram illustrating a configuration of a three-dimensional memory device 400 (e.g., memory devices 130 shown in FIG. 1). Memory device 400 includes a dynamic latch device 420 and logical SGDs 440. With reference to FIG. 4, the memory device 400 includes an array of memory cells (e.g., memory array 104, 200A, and 200B shown in FIGS. 1, 2A and 2B). In FIG. 4, the array of memory cells is illustrated using four memory strings 406a-406d (collectively as 406, e.g., NAND strings shown in FIGS. 2A-2C). It is understood that more memory strings or memory cells can be included in memory device 400. As shown in FIG. 4, the dynamic latch device 420 can be connected between the memory strings 406a-406d and a global bit line 404. In a physical layout of the memory device 400, the dynamic latch device 420 can be disposed above the memory strings 406.

As shown in FIG. 4, in one configuration, the dynamic latch device 420 includes a write transistor group 422 (e.g., denoted as WSG 422), a read transistor group 424 (e.g., denoted as RSG 424), and a storage device 426 (e.g., denoted as STFT). WSG 422, for example, can include one or more transistors controlled to allow transferring data from the global bit line 404 to the storage device 426. RSG 424 can include one or more transistors controlled to allow transferring data from the storage device 426 to the global bit line 404. The storage device 426 can store data on a sensing node (e.g., the gate of the storage device 426). The storage device 426 can further be connected to a regulated voltage source (e.g., denoted as RSRC), which can be used to perform certain operations like pre-charging. The various transistors in the dynamic latch device (e.g., RSG 424, WSG 422) can be controlled by the control logic (e.g., a local controller 135 shown in FIG. 1) of the memory device 400.

As shown in FIG. 4, the memory device 400 further includes multiple select gate drains 440a-440d (SGDs, collectively as 440) connected between the dynamic latch device 420 and the memory strings 406a-406d. In one configuration, the SGDs 440 are independent SGD and thus each memory string 406 is connected to a corresponding select gate drain (e.g., SGD0, SGD1, bSGD0, or bSGD1) transistor of the SGDs 440a-440d. In another configuration, the multiple SGDs 440 form logical SGDs with or without other transistors and logic gates (not shown). If SGDs 440 represent logical SGDs, FIG. 4 may be a simplified and symbolic diagram for illustration only, and does not necessarily show the actual transistors, logical gates, and/or connections used for implement the logical SGDs. The logical SGDs are collectively referred to as the SGDs 440. As described above, depending on the combination of its input signals, logical SGDs 440 can be configured to select a particular memory string from the four memory strings 406a-406d during a read operation. For example, the input signals of the logical SGDs 440 can be 00, 01, 10, and 11 (binary values), corresponding to selecting the memory strings 406a, 406b, 406c, and 406d, respectively. During the read operation, the control logic can control the dynamic latch device 420 for transferring data from the one or more memory strings 406 to the storage device 426, and from the storge device 426 to the global bit line 404. As shown in FIG. 4, in some examples, memory device 400 further includes data storage nodes 460a-460d (collectively as 460) connected between the SGDs 440 and the memory strings 406a-406d, respectively. The data storage nodes 460a-460d can be connected to capacitors (e.g., TC11, TC01, TC10, and TC00) configured to store data during read operations.

An example data access operation using the configuration shown in FIG. 4 is described next using a read operation as illustration. It is understood that other types of data access operations (e.g., a program verify operation) may be similarly performed. During a read operation, logical SGDs 440 receive a combination of input signals (e.g., voltages representing 00, 01, 10, or 11) to select one or more particular strings of memory cells 406 in the read operations. For example, SGD1 and SGD0 signals are raised to 6V, while bSGD1 and bSGD0 signals are grounded. This combination of the input signals to the logical SGD 440 can activate the SGDs 440a and 440b. Correspondingly, the memory string 406a and the memory string 406b are thus selected to be read. In general, as described above, different combinations of SGD0, SGD1, bSGD0 and bSGD1 signals can select different memory strings for reading. As a result, by using the logical SGDs 440, data can be read from memory cells in different memory strings 406a-406d. The data sensed from the memory cells of different memory strings 406 can be stored as charges on the capacitors (e.g., TC11, TC01, TC10, and TC00) connected to the data storage nodes 460a-460d. The logical SGDs 440 can also facilitate transferring the data stored on the data storage nodes 460a-460d to a sensing node of the dynamic latch device 420 (e.g., the sensing node can be the gate terminal of the storage device 426, which is denoted as STFT). In this configuration shown in FIG. 4, the sensing node of the dynamic latch device 420 may have a relatively large parasitic capacitance because it is connected to the logic SGDs 440, which has a large capacitance. The large parasitic capacitance may reduce the signal-to-noise ratio during the performance of the read operations. Therefore, there is a need for techniques to reduce parasitic capacitance and increase signal-to-noise ratio. The below description provides hierarchical logical SGDs to perform a group read operation or other types of data access operations of a memory array in a three-dimensional memory device.

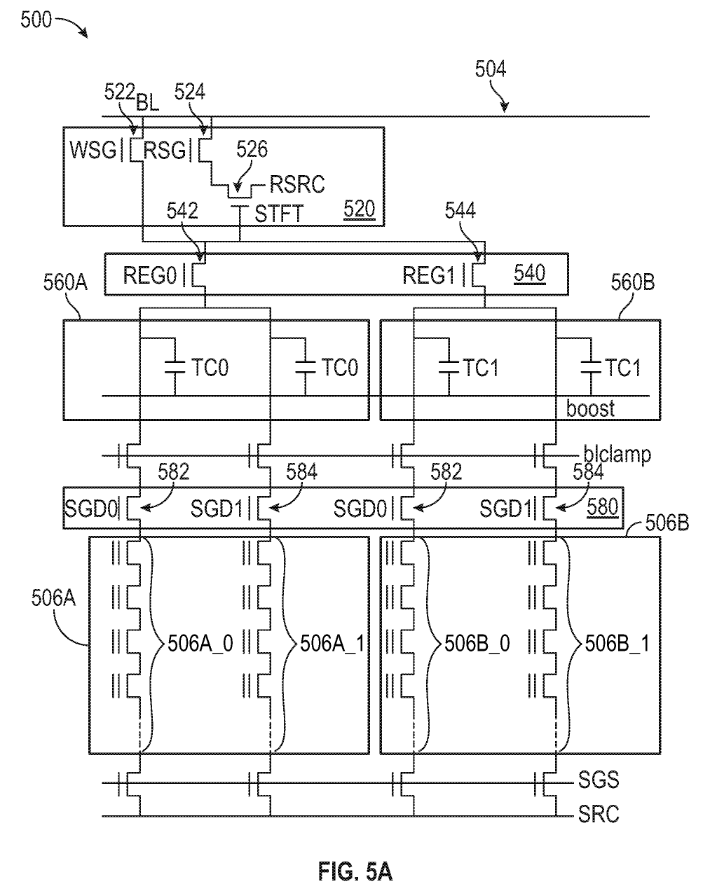

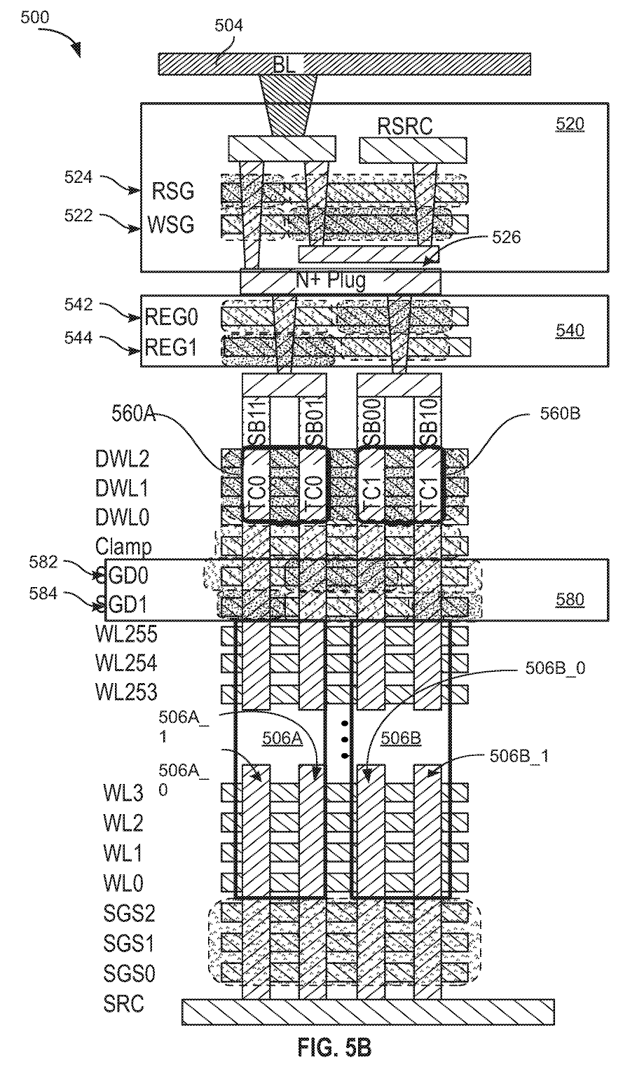

FIGS. 5A and 5B are diagrams illustrating an example of a memory device 500 (e.g., memory devices 130 shown in FIG. 1). Device 500 includes hierarchical select gate drain (SGD) structures. In particular, FIG. 5A illustrates a circuit diagram for device 500 and FIG. 5B illustrates a layout structure for the circuit diagram shown in FIG. 5A.

With reference to FIGS. 5A and 5B, the memory device 500 includes an array of memory cells (e.g., memory array 104, 200A, and 200B shown in FIGS. 1, 2A and 2B). The array of memory cells in device 500 can include tri-level memory cells (TLCs), quad-level memory cells (QLCs), and/or other types of memory cells. The array of memory cells includes multiple sets of memory strings like sets 506A and 506B. The memory strings in sets 506A and 506B can be the same or similar to memory strings shown in FIGS. 2A-2C. In the example shown in FIG. 5A, the sets of memory strings include a first set of memory strings 506A (e.g., two left memory strings 506A_0 and 506A_1) and a second set of memory strings 506B (e.g., two right memory strings 506B_0 and 506B_1). While FIGS. 5A and 5B illustrate an example in which a set of memory strings includes two memory strings, it is understood that more memory strings can be included in a set of memory strings. Further, it is also understood that more sets of memory strings can be included in a memory device.

With reference to FIGS. 5A and 5B, the memory device 500 further includes a global bit line (e.g., global bit line 504) and a dynamic latch device 520. As described above, in a configuration where logical SGDs are used to select memory strings during data access operations, large parasitic capacitance of the logical SGDs may affect the sensing node of the dynamic latch device and thus reduce the signal-to-noise ratio. To reduce parasitic capacitance and increase signal-to-noise ratio, the memory device 500 uses hierarchical SGD structures. As shown in FIGS. 5A and 5B, in the hierarchical SGD structures, at least some of the transistors in the logical SGDs are split into different tiers including a first tier select gates 540 and a second tier select gates 580. The dynamic latch device 520 is connected between the global bit line 504 and the first tier select gates 540. The second tier select gates 580 are connected between the first tier select gates 540 and the multiple sets of memory strings 506A and 506B.

The memory device 500 can further include a control logic (not shown in FIG. 5A) configured to control the first tier select gates 540 and the second tier select gates 580. The control logic can be the same or similar to controller 115 or 135 shown in FIG. 1. The control logic can be configured to control the first tier select gates 540 and the second tier select gates 580 to cause multiple selected memory strings (e.g., 506A_0, 506A_1, 506B_0, and/or 506B_1) of the sets of memory strings 506A and 506B to be read using the dynamic latch device 520 based on, for example, a single read pulse. A read pulse can be applied to a word line that is connected to memory cells in many memory strings, as illustrated in FIGS. 2A-2C.

In particular, as shown in FIGS. 5A and 5B, the first set of memory strings 506A is connected to a first data storage node 560A (e.g., the node connected to capacitors denoted as TC0). The first data storage node 560A is connected between the first tier select gates 540 and the second tier select gates 580. The second set of memory strings 506B is connected to a second data storage node 560B (e.g., the node connected to capacitors TC1). The second data storage node 560B is connected between the first tier select gates 540 and the second tier select gates 580. In the configuration shown in FIG. 5A, the first data storage node 560A is connected to one or more first capacitors (e.g., denoted as TC0) shared between multiple memory strings of the first set of memory strings 506A. The second data storage node 560B is connected to one or more second capacitors (e.g., denoted as TC1) shared between multiple memory strings of the first set of memory strings 506B. As shown in FIG. 5B, in some examples, the first data storage node 560A and second data storage node 560B are nodes formed by dummy word lines (denoted by DWL, e.g., DWL0, DWL1, and DWL2) implemented as capacitors.

With reference to FIGS. 5A and 5B, the first tier select gates 540 include a first control gate 542 (e.g., also referred to as REG0) and a second control gate 544 (e.g., also referred to as REG1). The first control gate 542 is connected to the first data storage node 560A. The second control gate 544 is connected to the second data storage node 560B. As shown in FIG. 5A, the second tier select gates 580 include a first set of SGDs 582 (e.g., referred to as the two SGD0s shown in FIG. 5A) and a second set of SGDs 584 (e.g., referred to as the two SGD1s shown in FIG. 5A). The first set of SGDs 582 (e.g., two SGD0s) is controlled by a first SGD control signal. The second set of SGDs 584 (e.g., two SGD1s) is controlled by a second SGD control signal. The first SGD control signal and the second SGD control signal are not shown in FIG. 5A, but can be applied to, for example, the gate terminals of the corresponding SGDs from the control logic.

With continued reference to FIG. 5A, the first set of memory strings 506A includes a first memory string 506A_0 and a second memory string 506A_1. The second set of memory strings 506B includes a third memory string 506B_0 and a fourth memory string 506B_1. As shown in FIG. 5A, the first memory string 506A_0 and the third memory string 506B_0 are connected to the first set of SGDs 582 (e.g., connected to SGD0s) controlled by the first SGD control signal. The second memory string 506A_1 and the fourth memory string 506B_1 are connected to the second set of SGDs 584 (e.g., connected to SGD1s) controlled by the second SGD control signal.

As shown in FIGS. 5A and 5B, the first tier select gates 540 include first tier transistors (e.g., transistors for implementing REG0 and REG1) extending over the first data storage node 560A and the second data storage node 560B. The first tier transistors are used to implement the first control gate 542 and the second control gate 544 of the first tier select gates 540. The first control gate 542 and the second control gate 544 (e.g., REG0 and REG1) are configured to receive first tier gate control signals for selecting one of the first data storage node 560A or the second data storage node 560B. For instance, the first control gate 542 can be controlled to select the first data storage node 560A. After the first data storage node 560A is selected, the data stored thereon can be transferred to the sensing node of storage device 526 in the dynamic latch device 520. Similarly, the second control gate 544 can be controlled to select the second data storage node 560B. After the second data storage node 560B is selected, the data stored thereon can be transferred to the sensing node of storage device 526 in the dynamic latch device 520. In some examples, the first data storage node 560A and 560B are selected in serial or alternatively, but not both at the same time, to avoid data corruption.

With continued reference to FIGS. 5A and 5B, the second tier select gates 580 include the second tier transistors (e.g., used to implement SGD0s and SGD1s) extending over the first set of memory strings 506A and the second set of memory strings 506B. The second tier transistors (e.g., SGD0s and SGD1s) are used to implement the first and second sets of SGDs 582 and 584, which are configured to receive the second tier control signals (e.g., the first SGD control signal and the second SGD control signal) for selecting one or more memory strings from the first and second sets of memory strings 506A and/or 506B.

As described above, a dynamic latch device can be used in a memory device for improving operational efficiency and throughput. Memory device 500 includes such a dynamic latch device 520. The dynamic latch device 520 has a write transistor group 522 (e.g., also referred to as WSG), a read transistor group 524 (e.g., also referred to as RSG), and a storage device 526 (e.g., also referred to as STFT). As shown in FIG. 5A, the write transistor group 522 can include one or more write transistors and is connected between the global bit line 504 and first tier select gates 540. The read transistor group 524 can include one or more read transistors and is connected between the global bit line 504 and the storage device 526. In the configuration as shown in FIG. 5A, the storage device 526 includes a transistor having a first terminal (e.g., gate terminal of the transistor) connected to the first tier select gates 540, a second terminal (e.g., source terminal of the transistor) connected to a regulated voltage source (e.g., also referred to as RSRC), and a third terminal (e.g., drain terminal of the transistor) connected to the read transistor group 524. In some embodiments, the storage device 526 includes a sense amplification transistor. The control logic (e.g., controller 135) controls the sense amplification transistor to provide sense amplification during a read operation of the sets of memory strings 506A and 506B. During the read operation, the sense amplification transistor of the storage device 526 amplifies a very small pillar current. The amplified current or voltage is transferred to a page buffer (e.g., a page buffer 152 shown in FIG. 1) via the global bit line 504. The page buffer is connected to the global bit line 504. The control logic is configured to perform operations to communicate data between the dynamic latch device 520 and the page buffer.

An example group read operation is described next. The group read operation uses the dynamic latch device 520 and the hierarchical SGD structures including the first tier select gates 540 and second tier select gates 580. During a group read operation, for example, the control logic (e.g., local controller 135) can be configured to control the first tier select gates 540 and the second tier select gates 580 to cause multiple selected memory strings of the sets of memory strings 506A and 506B to be read using the dynamic latch device 520. In some examples, the group read operations can be performed based on a single read pulse using the hierarchical SGD structures and the dynamic latch device described in this disclosure. Thus, during a group read operation, memory cells in multiple selected memory strings can be read in parallel. For example, the control logic can be configured to control the second tier select gates 580 to read data, in parallel, from multiple memory cells in the multiple selected memory strings.

In particular, the second tier select gates 580 can be implemented as logical SGDs and therefore controlled to select, for example, memory strings 506A_0 and 506B_0 to perform read operations, by turning on the part of the logical SGDs represented by the SGD0 in the second tier select gates 580. Referring to FIG. 5A, the control logic can active the first set of SGDs 582 (e.g., referred to as the SGD0s) in the second tier select gates 580. Upon activating, the stored data from a memory cell in string 506A_0 and the stored data from a memory cell in string 506B_0 can be transferred (e.g., read) to the first data storage node 560A and the second data storage node 560B, respectively. The data storage nodes 560A and 560B are connected between the first tier select gates 540 and the second tier select gates 580, and can be used as temporary caches to store data read from multiple memory strings. The capacitors TC0 and TC1 facilitate retaining the data on the storage nodes 560A and 560B, respectively.

Next, the control logic controls the first tier select gates 540 to read, in serial, the data stored on the data storage nodes 560A and 560B to a data storage device 526 of the dynamic latch device 520. For example, the control logic (e.g., local controller 135) activates (e.g., turns on) the first control gate 542 (e.g., referred to as REG0) to transfer the data stored on first data storage node 560A to the sensing node of the storage device 526 (e.g., the gate terminal of device 526). After the data transfer, the control logic can deactivate (e.g., turn off) the first control gate 542. The sensing node of the storage device 526 retains the data stored on it.

Next, the control logic controls the dynamic latch device 520 to provide the data stored at the data storage device 526 to the global bit line 504. For instance, the control logic can turn on the transistors in the read transistor group 524 to transfer the data stored on the sensing node of storage device 526 to global bit line 504. The data transferred to the global bit line 504 (e.g., in the form of a voltage or current) can be sensed by the page buffer (e.g., page buffer 152 shown in FIG. 1). After the data stored on the data storage device 526 of the dynamic latch device 520 is transferred to the global bit line 504, the dynamic latch device 520 can be controlled to receive new data. Thus, the control logic can activate (e.g., turn on) the second control gate 544 (e.g., denoted as REG 1) to transfer the data stored on storage node 560B (e.g., connected to TC1) to the sensing node of the storage device 526. Thus, in this example, the data stored on the storage nodes 560A and 560B are transferred in serial to the dynamic latch device 520. After the data stored on storage node 560B is transferred to the dynamic latch device 520, the control logic can deactivate (e.g., turn off) the second control gate 544. And the above process can be repeated to transfer the data further to the global bit line 504 for sensing by the page buffer.

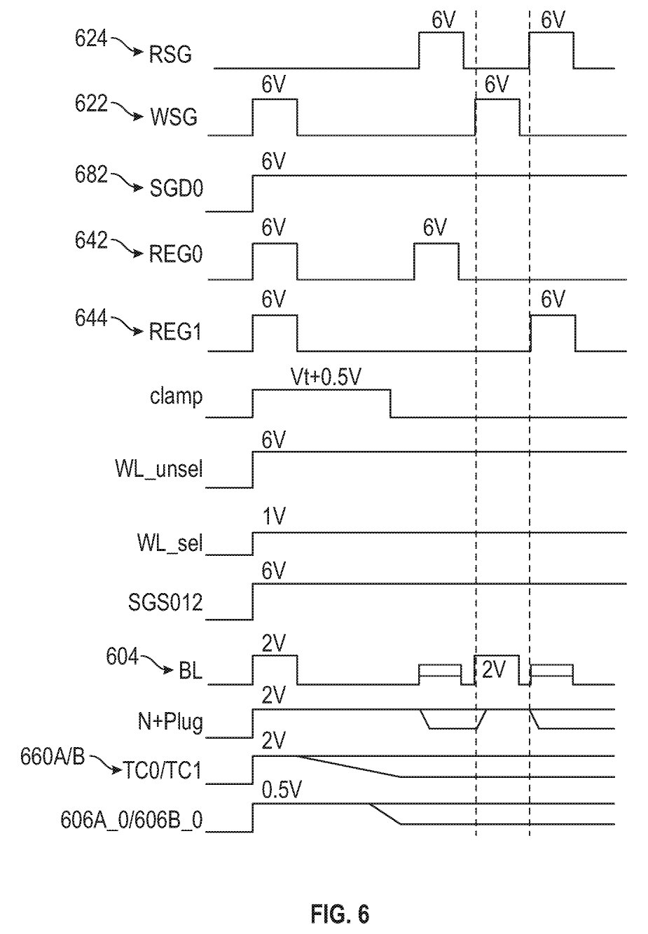

With continued reference to FIG. 5A, after the second control gate 544 is controlled to transfer data from storage node 560B to storage device 526, the control logic may control the second tier select gates 580 to perform further read operations such that new data is loaded onto storage nodes 560A and/or 560B. In other words, after the data stored on storage nodes 560A and 560B are transferred to storage device 526 (e.g., in serial), additional read operations from memory cells in the multiple memory strings 506A and 506B can be performed. In some examples, at this time, the data stored in the dynamic latch device 520 may still be in the process of being transferred to the global bit line 504 and/or the data transferred to the global bit line 504 may still be in the process of being sensed by the page buffer. Thus, as shown in FIGS. 5A and 5B, the hierarchical SGD structures and the dynamic latch device enable group read operations to be performed in parallel stages to increase the reading performance and throughput. In other words, using the hierarchical SGD structures and the dynamic latch device, the process of accessing data in the memory string and the process of transferring data to the global bit lines/sensing by the page buffer can be at least partially decoupled and performed in parallel. Examples of the group read operations and waveforms are described in further detail below with reference to FIG. 6. The hierarchical SGD structures further reduce parasitic capacitance at the sensing node of the storage device 526 by separating the logical SGDs to two or more tiers (in the example shown above, two tiers). As shown in FIG. 5B, the sensing node of the storage device 526 is only connected to the first tier select gates 540. The second tier select gates 580 are not directly connected to the sensing node, and therefore does not contribute, or contribute much less, parasitic capacitance. As a result, the signal-to-noise ratio can be improved, leading to lower error rates in data access operations like the group read operations.

FIG. 6 is a diagram illustrating example waveforms of signals associated with data access operations (e.g., group read operations) using a dynamic latch device and the hierarchical SGD structures (e.g., as shown in FIGS. 5A and 5B). In FIG. 6, the horizontal direction represents time and the vertical direction represents voltage. As described above, a memory device (e.g., device 130 or 500) includes an array of memory cells, which can include a plurality of sets of memory strings. FIG. 6 illustrates waveforms 606A_0 and 606B_0 (collectively as 606) of voltages applied to the word lines of memory cells in the memory strings. For example, waveform 606A_0 can represent the word line voltage applied to a memory cell in memory strings 506A_0; and waveform 606B_0 can represent the word line voltage applied to a memory cell of memory strings 506B_0. FIG. 6 further illustrates waveforms (e.g., 622 and 624) of voltages applied to circuits in the dynamic latch device. For example, waveforms 622 and 624 can represent the control voltages applied to write transistor group 522 (denoted as WSG) and read transistor group 524 (denoted as RSG), respectively. The example shown in FIG. 6 illustrates group read operations based on a single read pulse (as illustrated by the word line voltages or the word line select signal waveforms).

As described above in connection with FIGS. 5A and 5B, a memory device includes a controller configured to control a first tier select gates 540 (e.g., including REG0 and REG1) and a second tier select gates 580 (e.g., including SGD0 and SGD1). As shown in FIG. 6, waveforms 642 and 644 represent the voltages applied to the first tier select gates 540 (e.g., voltages applied to first control gate 542 or REG0 and second control gate 544 or REG1, respectively). Waveform 682 represents the voltage applied to the first set of SGDs 582 (e.g., denoted as SGD0s) of the second tier select gates 580.

With reference to FIGS. 5A, 5B and 6, during a group read operation, the control logic controls the first set of SGDs 582 (e.g., denoted as SGD0) of the second tier select gates 580 to read data, in parallel, from the multiple selected memory strings and transfer the sensed data to data storage nodes 560A and 560B (e.g., denoted as TC0 or TC1). The data storage nodes 560A and 560B are connected between the first tier select gates 540 and the second tier select gates 580. As shown in FIG. 6, waveforms 660A and 660B represent voltages of the first data storage node 560A (e.g., connected to capacitors denoted as TC0) and the second data storage node 560B (e.g., connected to capacitors denoted as TC1), respectively. With reference to both FIGS. 5A, 5B and 6, the control logic activates (e.g., turns on) the first set of SGDs 582 (e.g., SGD0s) in the second tier select gates 580 (e.g., waveform 682 shows that the voltage applied to the SGD0 increases from low to high) to read the data in parallel from the memory strings 506A_0 and 506B_0, and cause the data to be transferred to a corresponding data storage nodes 560A and 560B respectively. For instance, the control logic can cause the data to be transferred from the memory string 506A_0 to the first data storage node 560A (connected to a capacitor TC0). The control logic can cause the data to be transferred from the memory string 506B_0 to the second data storage node 560B (connected to the capacitor TC1). Waveforms 660A and 660B show that the voltages retained by the storage nodes 560A and 560AB (connected to capacitors TC0/TC1) may be affected by the data, depending on the voltage levels of the data.

With continued reference to FIGS. 5A, 5B, and 6, the control logic controls the first tier select gates 540 (e.g., including REG0 or REG1) to read, in serial, the data stored at the data storage nodes 560A and 560B (e.g., connected to capacitors TC0 or TC1) to the data storage device 526 of the dynamic latch device 520. Further, the control logic controls the dynamic latch device 520 to provide, in serial, the data stored at the dynamic latch device 520 to a global bit line 504. In particular, as shown in FIG. 6, for the data originally sensed from the memory string 506A_0, the control logic activates (e.g., turns on) the first control gate 542 (e.g., denoted as REG0) in the first tier select gates 540 to transfer the data from the first data storage node 560A (e.g., connected to TC0) to the dynamic latch device 520. Thus, waveform 642 shows that the voltage applied to REG0 increases from low to high to activate the first control gate 542. Afterwards, the control logic also activates (e.g., turns on) the read transistor group 524 (denoted as RSG, see waveform 624 which shows the RSG is activated) of the dynamic latch device 520 to provide the data to the global bit line 504. The waveform 604 for the bit line 504 shows that after the activation of the RSG, the voltage levels of the bit line 504 may change depending on the voltage levels of the data (e.g., either low or high).

As for the data originally from the memory string 506B_0, the control logic activates (e.g., turns on) the second control gate 544 (e.g., denoted as REG1) in the first tier select gates 540 (see waveform 644) to transfer the data from the second data storage node 560B (e.g., connected to TC1) to the dynamic latch device 520. FIG. 6 illustrates that the control logic can activate (e.g., turn on) the read transistor group (denoted as RSG) at the same time (see waveform 624) and causes the dynamic latch device 520 to provide the data to the global bit line 504. In other examples, the RSG turns on after the REG1 turns on. The waveform 604 represents the voltage changes of global bit line 504 and as shown, after the RSG is turned on, the voltage of the global bit line 504 changes according to the data sensed (e.g., either low or high). In this example, the controller turns on and off WSG to reset the dynamic latch device 520 before the first and second control gates 542 and 544 (REG0 or REG1) turning on to improve signal to noise ratio.

FIGS. 5A and 6 illustrate an example of controlling the first tier select gates 540 and the second tier select gates 580 to group read data from the memory strings 506A_0 and 506B_0 to the global bit line. The group read operation can be performed based on a single read pulse (e.g., a single read pulse applied to the selected word line, as shown by the waveforms 606 and/or the waveform for WL_sel). It is understood that the control logic can also use a similar method to group read data from the memory strings 506A_1 and 506B_1 to the global bit line. That is, the control logic activates (e.g., turns on) SGD1 (not shown in FIG. 6) in the second tier select gates 580 to read the data in parallel from the memory strings 506A_1 and 506B_1 to a corresponding data storage node 560A and 560B (connected to capacitors TC0 or TC1). Serially, the control logic turns on REG0 in the first tier select gates 540 to transfer the data originally form the memory string 506A_1, from the first data storage node 560A (TC0) to the dynamic latch device 520. The control logic also turns on RSG of the dynamic latch device 520 to provide the data to the global bit line 504. As for the data originally form the memory string 506B_1, the control logic activates (e.g., turns on) REG1 in the first tier select gates 540 to transfer the data from the second data storage node 560B (TC1) to the dynamic latch device 520. The control logic turns on read transistor group 524 (RSG) at the same time (or after turning on the REG1) and causes the dynamic latch device 520 to provide the data to the global bit line 504.

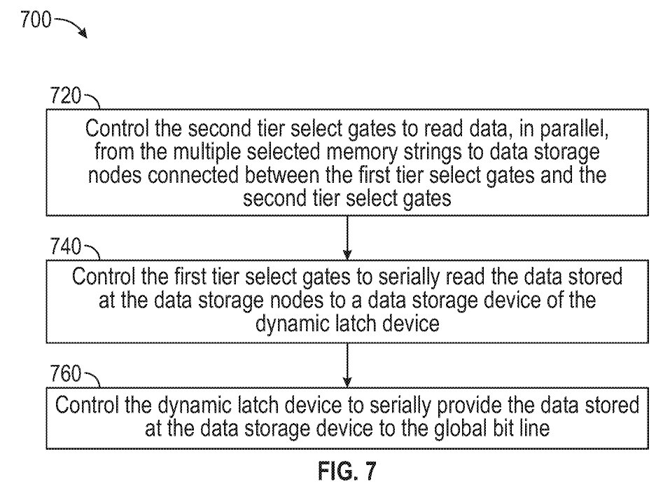

FIG. 7 is a flowchart illustrating an example process 700 for performing a group read operation of a memory array of a three-dimensional memory device using hierarchical SGD structures according to the embodiments disclosed herein. The memory device (e.g., memory devices 130 or 500 shown in FIGS. 1, 5A and 5B) includes an array of memory cells having multiple sets of memory strings (e.g., sets of memory strings 506A and 506B shown in FIGS. 5A-5B). The memory device includes hierarchical SGD structures having a first tier select gates (e.g., gates 540) and a second tier select gates (e.g., gates 580). The memory device further includes a global bit line (e.g., global bit line 504), and a dynamic latch device (e.g., device 520) connected between the global bit line and the first tier select gates. The second tier select gates are connected between the first tier select gates and multiple sets of memory strings. The memory device further includes control logic (e.g., local controller) configured to control the first tier select gates and the second tier select gates. The control logic controls the first tier select gates and the second tier select gates to cause multiple selected memory strings of the plurality of sets of memory strings to be read using the dynamic latch device based on a single read pulse.

In block 720 of process 700, the control logic controls the second tier select gates to read data, in parallel, from the multiple selected memory strings to data storage nodes (e.g., nodes 560A and 560B). The data storage nodes are connected between the first tier select gates and the second tier select gates.

In block 740 of process 700, the control logic controls the first tier select gates to serially read the data stored at the data storage nodes to a data storage device of the dynamic latch device.

In block 760 of process 700, the controller controls the dynamic latch device to provide the data stored at the data storage device to the global bit line in serial.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “controller” is used interchangeably with the term “control logic” to refer to any circuitry or blocks that performs control functions and/or other functions associated with performing operations associated with memory devices. The control logic can include firmware and/or software executed or implemented in hardware circuits. In this disclosure, the control logic in some examples can include the controllers (e.g., local controller, system controller, etc.). In other examples, the control logic can include other blocks or circuitry (e.g., sense amplifiers, latches, buffers, registers, decoders, etc.), but not the array of memory cells.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and include a three terminal device including a source, drain, and gate. The terminals may be connected to other electronic elements through conductive materials, e.g., metals. The source and drain may be conductive and may include a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A three-dimensional memory device comprising:
an array of memory cells comprising a plurality of sets of memory strings;
a global bit line;
a first tier select gates;
a dynamic latch device connected between the global bit line and the first tier select gates;
a second tier select gates connected between the first tier select gates and the plurality of sets of memory strings; and
control logic configured to control the first tier select gates and the second tier select gates to cause multiple selected memory strings of the plurality of sets of memory strings to be read using the dynamic latch device.

2. The three-dimensional memory device of claim 1, wherein the plurality of sets of memory strings comprises:
a first set of memory strings connected to a first data storage node, the first data storage node being connected between the first tier select gate and the second tier select gate; and
a second set of memory strings connected to a second data storage node, the second data storage node being connected between the first tier select gates and the second tier select gate.

3. The three-dimensional memory device of claim 2, wherein:
the first data storage node comprises a first capacitor shared between multiple memory strings of the first set of memory strings; and
the second data storage node comprises a second capacitor shared between multiple memory strings of the second set of memory strings.

4. The three-dimensional memory device of claim 2, wherein the first tier select gates comprise a first control gate and a second control gate, the first control gate being connected to the first data storage node, and the second control gate being connected to the second data storage node.

5. The three-dimensional memory device of claim 2, wherein the second tier select gates comprise a first set of select gate drains (SGDs) controlled by a first SGD control signal and a second set of SGDs controlled by a second SGD control signal.

6. The three-dimensional memory device of claim 5, wherein the first set of memory strings comprises a first memory string and second memory string, and the second set of memory strings comprises a third memory string and a fourth memory string, and wherein:
the first memory string and the third memory string are connected to the first set of SGDs controlled by the first SGD control signal; and
the second memory string and the fourth memory string are connected to the second set of SGDs controlled by the second SGD control signal.

7. The three-dimensional memory device of claim 2, wherein the first tier select gates comprise a plurality of first tier transistors configured to receive first tier gate control signals for selecting one of the first data storage node or the second data storage node.

8. The three-dimensional memory device of claim 2, wherein the second tier select gates comprise a plurality of second tier transistors configured to receive second tier control signals for selecting a memory string of the first and second sets of memory strings.

9. The three-dimensional memory device of claim 1, wherein the dynamic latch device comprises:
a write transistor group comprising one or more write transistors, wherein the write transistor group is connected between the global bit line and first tier select gates;
a storage device; and
a read transistor group comprising one or more read transistors, wherein the read transistor group is connected between the global bit line and the storage device.

10. The three-dimensional memory device of claim 9, wherein the storage device comprises a transistor having a first terminal connected to the first tier select gates, a second terminal connected to a regulated voltage source, and a third terminal connected to the read transistor group.

11. The three-dimensional memory device of claim 9, wherein the storage device comprises a sense amplification transistor controlled by the controller to provide sense amplification during a read operation of the plurality of sets of memory strings.

12. The three-dimensional memory device of claim 1, wherein the control logic being configured to control the first tier select gates and the second tier select gates to cause the multiple selected memory strings to be read using the dynamic latch device comprises:
controlling the second tier select gates to read data, in parallel, from the multiple selected memory strings to data storage nodes connected between the first tier select gates and the second tier select gates;
controlling the first tier select gates to read, in serial, the data stored at the data storage nodes to a data storage device of the dynamic latch device; and
controlling the dynamic latch device to provide, in serial, the data stored at the data storage device to the global bit line.

13. The three-dimensional memory device of claim 1, further comprising a page buffer connected to the global bit line, wherein the controller is further configured to perform operations to communicate data between the dynamic latch device and the page buffer.

14. The three-dimensional memory device of claim 1, wherein the array of memory cells comprises tri-level or quad-level memory cells.

15. The three-dimensional memory device of claim 1, wherein the control logic is configured to control the first tier select gates and the second tier select gates to cause the multiple selected memory strings to be read based on a single read pulse.

16. A memory system comprising:
a system controller; and
a memory device of claim 1, the memory device being coupled to the system controller.

17. A method for performing a group read operation of a memory array of a three-dimensional memory device comprising a first tier select gates and a second tier select gates, the method comprising:
controlling the second tier select gates to read data, in parallel, from multiple selected memory strings of a plurality of sets of memory strings to data storage nodes connected between the first tier select gates and the second tier select gates;
controlling the first tier select gates to read, in serial, the data stored at the data storage nodes to a data storage device of a dynamic latch device; and
controlling the dynamic latch device to provide, in serial, the data stored at the data storage device to a global bit line.
